(19) United States
(12) Patent Application Publication
(10) Pub. No.: US 2026/0052737 A1
(43) Pub. Date: Feb. 19, 2026

(54) EMBEDDED MULTI-TIME PROGRAMMABLE (MTP) FLOATING GATE MEMORY IN A SEMICONDUCTOR-ON-INSULATOR (SOI) COMPLEMENTARY METAL OXIDE SEMICONDUCTOR (CMOS) PROCESS

(71) Applicant: QUALCOMM Incorporated, San Diego, CA (US)

(72) Inventors: Abhijeet PAUL, San Diego, CA (US); Yufei WU, San Diego, CA (US); Mishel MATLOUBIAN, San Diego, CA (US); Periannan CHIDAMBARAM, San Diego, CA (US)

(21) Appl. No.: 18/802,846

(22) Filed: Aug. 13, 2024

(51) Int. Cl. H01L 29/423; H01L 21/762; H01L 29/78; H10B 41/30

(52) U.S. Cl. CPC H10D 30/6892; H01L 21/76243; H10B 41/30; H10D 30/711; H10D 64/514

(57) ABSTRACT

A multi-time programable (MTP) memory cell is described. The MTP memory cell includes a buried oxide (BOX) layer. The MTP memory cell also includes a semiconductor-on-insulator (SOI) layer on the BOX layer. The MTP memory cell further includes a planar multi-gate structure. The planar multi-gate structure includes a pass-gate on the SOI layer. The planar multi-gate structure also includes a memory-gate.

### TECHNICAL FIELD

Certain aspects of the present disclosure relate to artificial neural networks and, more particularly, to a method and apparatus to make embedded multi-time programmable (MTP) floating gate memory in a semiconductor-on-insulator (SOI) complementary metal oxide semiconductor (CMOS) process.

### BACKGROUND

An artificial neural network, which may include an interconnected group of artificial neurons, may be a computational device or may represent a method to be performed by a computational device. Artificial neural networks may have corresponding structure and/or function in biological neural networks. Artificial neural networks, however, may provide useful computational techniques for certain applications, in which traditional computational techniques may be cumbersome, impractical, or inadequate. Because artificial neural networks may infer a function from observations, such networks may be useful in applications where the complexity of the task and/or data makes the design of the function burdensome using conventional techniques.

Neuromorphic computing (NC) imitates the functions of the brain by utilizing a network of synthetic neurons interconnected among synaptic devices. Currently, implementation of neuromorphic neural hardware activation functions relies on bulky, power-hungry designs, such as static random-access memory (SRAM)-based as well as comparator-based designs. Unfortunately, these SRAM-based and comparator-based designs exhibit a large footprint, which significantly increases the size of an integrated circuit (IC) incorporating these designs. An embedded multi-time programmable (MTP) floating gate memory in a semiconductor-on-insulator (SOI) complementary metal oxide semiconductor (CMOS) process to enable neuromorphic neural hardware multiply-accumulate (MAC) functions is desired.

### SUMMARY

A multi-time programable (MTP) memory cell is described. The MTP memory cell includes a buried oxide (BOX) layer. The MTP memory cell also includes a semiconductor-on-insulator (SOI) layer on the BOX layer. The MTP memory cell further includes a planar multi-gate structure. The planar multi-gate structure includes a pass-gate on the SOI layer. The planar multi-gate structure also includes a memory-gate.

A processor-implemented method for formation of a multi-time programmable (MTP) memory cell is described. The method includes depositing a semiconductor-on-insulator (SOI) layer on a buried oxide (BOX) layer of a semiconductor substrate. The method also includes forming a planar multi-gate structure from the SOI layer. The planar multi-gate structure includes a pass-gate on the SOI layer. The planar multi-gate structure also includes a memory-gate.

This has outlined, broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for conducting the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

The features, nature, and advantages of the present disclosure will become more apparent from the detailed description set forth below when taken in conjunction with the drawings in which like reference characters identify correspondingly throughout.

FIG. 1 illustrates an example implementation of a neuromorphic computing (NC) hardware activation (NCHWA) for a neural network using a system-on-chip (SoC), including a general-purpose processor, in accordance with certain aspects of the present disclosure.

FIGS. 2A, 2B, and 2C are diagrams illustrating a neural network, in accordance with various aspects of the present disclosure.

FIG. 2D is a diagram illustrating a neural network, in accordance with various aspects of the present disclosure.

FIGS. 3A and 3B are diagrams illustrating a neuromorphic network of synthetic neurons interconnected among synaptic devices to imitate the functions of the brain, according to various aspects of the present disclosure.

FIG. 4 illustrates a cross-sectional view of an embedded multi-time programmable (MTP) memory cell implementation of the multiply-accumulate (MAC) portion of FIG. 3B, according to various aspects of the present disclosure.

FIG. 5 illustrates a cross-sectional view of an embedded multi-time programmable (MTP) memory cell implementation of the multiply-accumulate (MAC) portion of FIG. 3B, according to various aspects of the present disclosure.

FIGS. 6A and 6B illustrate a circuit diagram and a corresponding block diagram of the embedded multi-time programmable (MTP) memory cell of FIG. 5, according to various aspects of the present disclosure.

FIGS. 7A and 7B illustrate cross-sectional views of embedded multi-time programmable (MTP) memory cell implementations of the multiply-accumulate (MAC) portion of FIG. 3B, according to various aspects of the present disclosure.

FIGS. 8A and 8B illustrate layout and cross-sectional views of embedded multi-time programmable (MTP) memory cell implementations of the multiply-accumulate (MAC) portion of FIG. 3B, according to various aspects of the present disclosure.

FIG. 9 is a flow diagram illustrating a process for embedded multi-time programmable (MTP) memory cell formation, according to various aspects of the present disclosure.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. Nevertheless, it will be apparent to those skilled in the art that these concepts may be practiced without these specific details. In some instances, well-known structures and components are shown in block diagram form to avoid obscuring such concepts.

Based on the teachings, one skilled in the art should appreciate that the scope of the disclosure is intended to cover any aspect of the disclosure, whether implemented independently of or combined with any other aspect of the disclosure. For example, an apparatus may be implemented, or a method may be practiced using any number of the aspects set forth. In addition, the scope of the disclosure is intended to cover such an apparatus or method practiced using other structure, functionality, or structure and functionality in addition to or other than the various aspects of the disclosure set forth. Any aspect of the disclosure disclosed may be embodied by one or more elements of a claim.

Although aspects are described, many variations and permutations of these aspects fall within the scope of the disclosure. Although some benefits and advantages of the preferred aspects are mentioned, the scope of the disclosure is not intended to be limited to benefits, uses, or objectives. Rather, aspects of the disclosure are intended to be universally applicable to different technologies, system configurations, networks, and protocols, some of which are illustrated by way of example in the figures and in the following description of the preferred aspects. The detailed description and drawings are merely illustrative of the disclosure, rather than limiting the scope of the disclosure being defined by the appended claims and equivalents thereof.

Neuromorphic computing (NC) imitates the functions of the brain by utilizing a network of synthetic neurons interconnected among synaptic devices. Currently, implementation of neuromorphic neural hardware activation functions relies on bulky, power-hungry designs, such as static random-access memory (SRAM)-based as well as comparator-based designs. Unfortunately, these SRAM-based and comparator-based designs exhibit a large footprint, which significantly increases the size of an integrated circuit (IC) incorporating these designs. Additionally, conventional implementation of neuromorphic neural hardware activation functions relies on a substantial number of active devices, which consume a significant amount of power in the digital domain.

Neuromorphic computing implementations incur a memory wall and an energy efficiency bottleneck in the von Neumann system due to the stagnation of Moore's law. An ideal artificial neuron possessing bio-inspired behaviors as exemplified by the requisite leaky-integrate-fire and self-reset (LIFR) functionalities within a single device is still lacking. Additionally, because the neural network hardware for performing inference is dense, successful implementation of neural network hardware involves artificial neuron cells exhibiting desired qualities, such as non-volatile memory. For example, artificial neuron cells exhibiting desired electrical behavior, while consuming a smaller area, may benefit from an analog implementation for lower energy consumption.

Non-volatile memories (NVM) may include memory cells as basic switching elements to store data. A one-time programmable (OTP) non-volatile memory is a form of digital memory in which a set value of each bit is locked by a fuse or anti-fuse. In an OTP memory, the set value of each bit cell cannot be reset. By contrast, in a multi-time programmable (MTP) memory, several write cycles can be supported, versus the OTP memory, in which data is permanently stored and cannot be changed.

One type of MTP memory is embedded flash memory. Embedded flash memories commonly use floating gate devices. In practice, conventional embedded flash memories are implemented using dual polysilicon layers. Dual polysilicon layers, however, suffer from the following limitations: (1) dual polysilicon layers are not accessible in all process technologies; and (2) dual polysilicon layers are expensive. Alternatively, embedded flash memories may be implemented using a special tunnel oxide/nitride/block oxide (ONO) type gate stack, which involves additional processing to provide the multiple gate oxides.

To avoid the shortcomings of conventional embedded flash memories, a novel, embedded MTP floating gate memory is implemented utilizing a semiconductor-on-insulator (SOI) complementary metal oxide semiconductor (CMOS) process is described. In some implementations, an embedded MTP floating gate memory is formed using an SOI CMOS process. An embedded MTP memory cell includes a buried oxide (BOX) layer and an SOI layer on the BOX layer. In various aspects of the present disclosure, the embedded MTP memory cell further includes a planar (e.g., flat, or coplanar) multi-gate structure, having a pass-gate on the SOI layer, and a memory-gate. The pass-gate may have a first gate oxide thickness and the memory-gate may have a second gate oxide thickness greater than the first gate oxide thickness.

According to various aspects of the present disclosure, existing transistor-based conventional embedded flash memories are replaced with floating gate charge trap multi-programable memories. In operation, programming of an embedded MTP floating gate memories is performed during the inference fine tuning (or downloading of the neural network weights) via a memory controller. Additionally, erasing of the embedded MTP floating gate memories is rarely performed because the values of the neural network weights used for inferencing in edge neural networks are usually fixed. As a result, the disclosed embedded MTP floating gate memories have memory endurance (e.g., number of program erase cycles) specifications (e.g., ˜100 program/erase cycles).

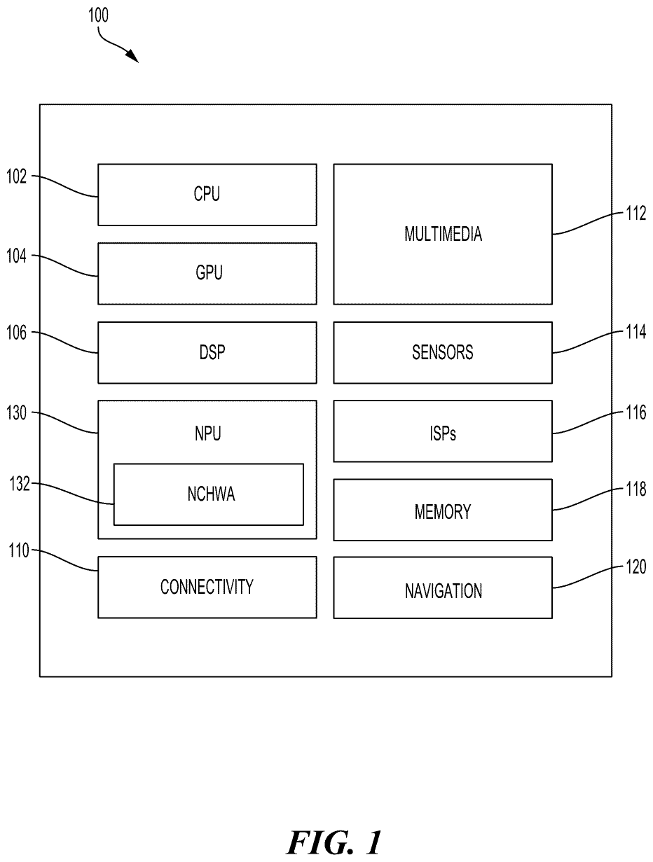

FIG. 1 illustrates an example implementation of a neuromorphic computing (NC) hardware activation (NCHWA) for a neural network using a system-on-chip (SoC), including a general-purpose processor, in accordance with certain aspects of the present disclosure. Variables (e.g., neural signals and synaptic weights), system parameters associated with a computational device (e.g., neural network with weights), delays, frequency bin information, and task information may be stored in a memory block associated with a neural processing unit (NPU) 130, in a memory block associated with a CPU 102, in a memory block associated with a graphics processing unit (GPU) 104, in a memory block associated with a digital signal processor (DSP) 106, in a memory block 118, or may be distributed across multiple blocks. Instructions executed at the CPU 102 may be loaded from a program memory associated with the CPU 102 or may be loaded from a memory block 118.

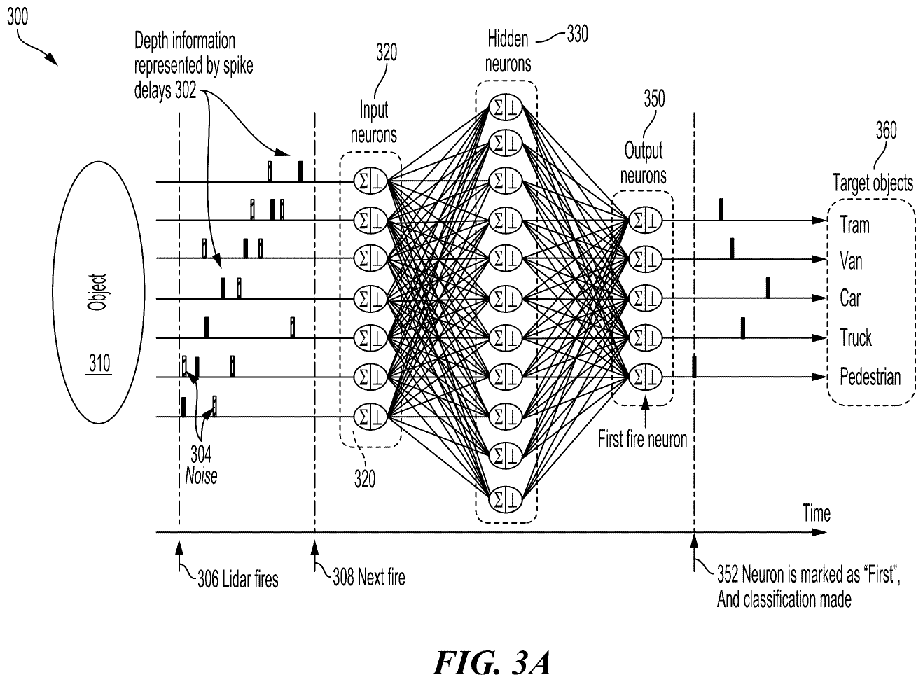

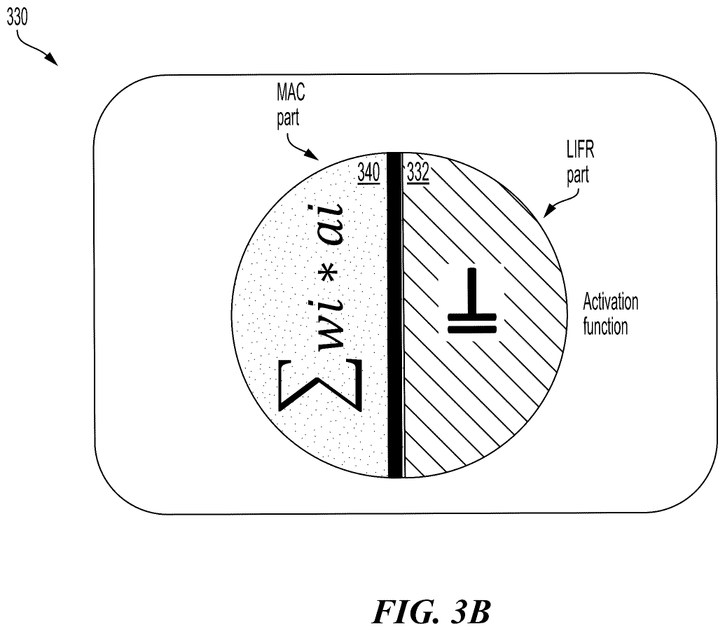

One aspect of the present disclosure is directed to a neuromorphic computing (NC) hardware activation (NCHWA) 132 of the NPU 130. Various aspects of the present disclosure are directed to an embedded multi-time programmable (MTP) floating gate memory utilizing a semiconductor-on-insulator (SOI) complementary metal oxide semiconductor (CMOS) cell to enable neuromorphic neural hardware multiply-accumulate (MAC) functions of the NCHWA 132 of the NPU 130. An embedded MTP memory cell includes a planar multi-gate structure, having a pass-gate on an SOI layer, and a memory-gate. In various aspects of the present disclosure, the embedded MTP memory cell exhibits various advantages. These advantages include a single polysilicon layer design, which provides a simplified implementation in any process. Additionally, the embedded MTP memory cell avoids a specialized gate stack by utilizing a predetermined gate oxide thickness. The embedded MTP memory cell utilizing either an N-type or P-type field effect transistor (FET) implementation overcomes conventional one-time programmable (OTP) memories, for example, as shown in FIG. 3A.

The SoC 100 may also include additional processing blocks tailored to specific functions, such as a connectivity block 110, which may include fifth generation (5G) new radio (NR) connectivity, fourth generation long term evolution (4G LTE) connectivity, unlicensed Wi-Fi connectivity, USB connectivity, Bluetooth® connectivity, and the like, and a multimedia processor 112 that may, for example, detect and recognize gestures. In one implementation, the NPU is implemented in the CPU, DSP, and/or GPU. The SoC 100 may also include a sensor processor 114 to provide sensor image data, image signal processors (ISPs) 116, and/or navigation module 120, which may include a global positioning system.

Deep learning architectures may perform an object recognition task by learning to represent inputs at successively higher levels of abstraction in each layer, thereby building up a useful feature representation of the input data. In this way, deep learning addresses a major bottleneck of traditional machine learning. Prior to the advent of deep learning, a machine learning approach to an object recognition problem may have relied heavily on human engineered features, in combination with a shallow classifier. A shallow classifier may be a two-class linear classifier, for example, in which a weighted sum of the feature vector components may be compared with a threshold to predict to which class the input belongs. Human engineered features may be templates or kernels tailored to a specific problem domain by engineers with domain expertise. Deep learning architectures, in contrast, may learn to represent features that are like what a human engineer might design, but through training. Furthermore, a deep network may learn to represent and recognize new types of features that a human might not have considered.

A deep learning architecture may learn a hierarchy of features. If presented with visual data, for example, the first layer may learn to recognize simple features, such as edges, in the input stream. In another example, if presented with auditory data, the first layer may learn to recognize spectral power in specific frequencies. The second layer, taking the output of the first layer as input, may learn to recognize combinations of features, such as simple shapes for visual data or combinations of sounds for auditory data. For instance, higher layers may learn to represent complex shapes in visual data or words in auditory data. Still higher layers may learn to recognize common visual objects or spoken phrases.

Deep learning architectures may perform especially well when applied to problems that have a natural hierarchical structure. For example, the classification of motorized vehicles may benefit from first learning to recognize wheels, windshields, and other features. These features may be combined at higher layers in diverse ways to recognize cars, trucks, and airplanes.

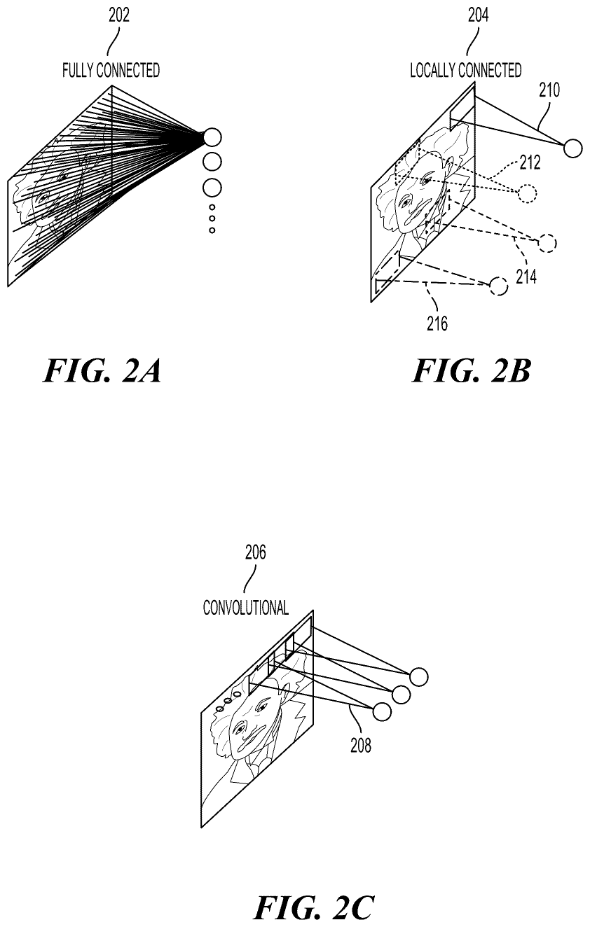

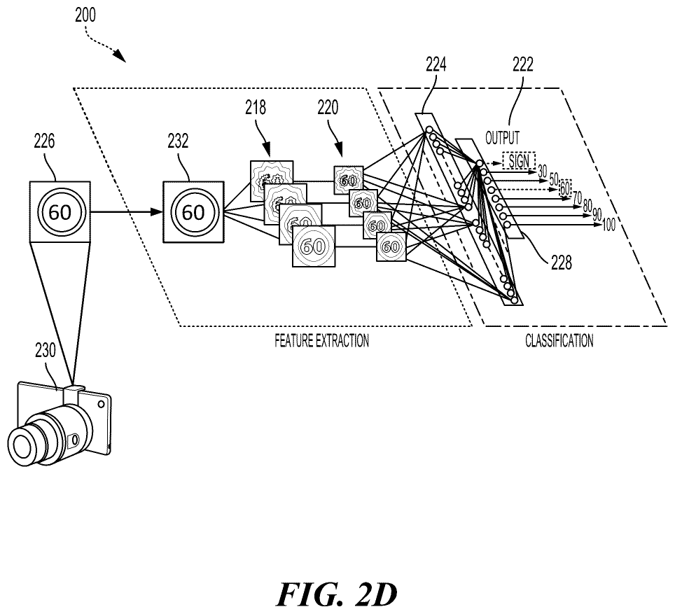

Neural networks may be designed with a variety of connectivity patterns. In feed-forward networks, information is passed from lower to higher layers, with each neuron in each layer communicating to neurons in higher layers. A hierarchical representation may be built up in successive layers of a feed-forward network, as described above. Neural networks may also have recurrent or feedback (also called top-down) connections. In a recurrent connection, the output from a neuron in each layer may be communicated to another neuron in the same layer. A recurrent architecture may be helpful in recognizing patterns that span more than one of the input data chunks that are delivered to the neural network in a sequence. A connection from a neuron in each layer to a neuron in a lower layer is called a feedback (or top-down) connection. A network with many feedback connections may be helpful when the recognition of a high-level concept may aid in discriminating the low-level features of an input. The connections between layers of a neural network may be fully connected or locally connected, for example, as shown in FIGS. 2A, 2B, and 2C.

FIGS. 2A, 2B, and 2C are diagrams illustrating a neural network, in accordance with various aspects of the present disclosure. FIG. 2A illustrates an example of a fully connected neural network 202. In a fully connected neural network 202, a neuron in a first layer may communicate its output to every neuron in a second layer, so that each neuron in the second layer will receive input from every neuron in the first layer. FIG. 2B illustrates an example of a locally connected neural network 204. In a locally connected neural network 204, a neuron in a first layer may be connected to a limited number of neurons in the second layer. More generally, a locally connected layer of the locally connected neural network 204 may be configured so that each neuron in a layer will have the same or a similar connectivity pattern, but with connection strengths that may have different values (e.g., 210, 212, 214, and 216). The locally connected connectivity pattern may give rise to spatially distinct receptive fields in a higher layer because the higher layer neurons in each region may receive inputs that are tuned through training to the properties of a restricted portion of the total input to the network.

One example of a locally connected neural network is a convolutional neural network. FIG. 2C illustrates an example of a convolutional neural network 206. The convolutional neural network 206 may be configured such that the connection strengths associated with the inputs for each neuron in the second layer are shared (e.g., 208). Convolutional neural networks may be well suited to problems in which the spatial location of inputs is meaningful. One type of convolutional neural network is a deep convolutional network (DCN).

FIG. 2D is a diagram illustrating a neural network, in accordance with various aspects of the present disclosure. FIG. 2D illustrates a detailed example of a DCN 200 designed to recognize visual features from an image 226 input from an image capturing device 230, such as a car-mounted camera. The DCN 200 of the current example may be trained to identify traffic signs and a number provided on the traffic sign. Of course, the DCN 200 may be trained for other tasks, such as identifying lane markings or identifying traffic lights.

The DCN 200 may be trained with supervised learning. During training, the DCN 200 may be presented with an image, such as the image 226 of a speed limit sign, and a forward pass may then be computed to produce an output 222. The DCN 200 may include a feature extraction section and a classification section. Upon receiving the image 226, a convolutional layer 232 may apply convolutional kernels (not shown) to the image 226 to generate a first set of feature maps 218. As an example, the convolutional kernel for the convolutional layer 232 may be a 5×5 kernel that generates 28×28 feature maps. In the present example, because four different convolutional kernels were applied to the image 226 at the convolutional layer 232, four different feature maps are generated in the first set of feature maps 218. The convolutional kernels may also be referred to as filters or convolutional filters.

The first set of feature maps 218 may be subsampled by a max pooling layer (not shown) to generate a second set of feature maps 220. The max pooling layer reduces the size of the first set of feature maps 218. That is, a size of the second set of feature maps 220, such as 14×14, is less than the size of the first set of feature maps 218, such as 28×28. The reduced size provides similar information to a subsequent layer while reducing memory consumption. The second set of feature maps 220 may be further convolved via one or more subsequent convolutional layers (not shown) to generate one or more subsequent sets of feature maps (not shown).

In the example of FIG. 2D, the second set of feature maps 220 is convolved to generate a first feature vector 224. Furthermore, the first feature vector 224 is further convolved to generate a second feature vector 228. Each feature of the second feature vector 228 may include a number that corresponds to a feature of the image 226, such as “sign,” “60,” and “100.” A SoftMax function (not shown) may convert the numbers in the second feature vector 228 to a probability. As such, an output 222 of the DCN 200 is a probability of the image 226 including one or more features.

In the present example, the probabilities in the output 222 for “sign” and “60” are higher than the probabilities of the others of the output 222, such as “30,” “40,” “50,” “70,” “80,” “90,” and “100.” Before training, the output 222 produced by the DCN 200 is likely to be incorrect. Thus, an error may be calculated between the output 222 and a target output. The target output is the ground truth of the image 226 (e.g., “sign” and “60”). The weights of the DCN 200 may then be adjusted so the output 222 of the DCN 200 is more closely aligned with the target output to perform neuromorphic computing.

Neuromorphic computing (NC) imitates the functions of the brain by utilizing a network of synthetic neurons interconnected among synaptic devices. Currently, implementation of neuromorphic neural hardware activation functions rely on bulky, power-hungry designs, such as static random-access memory (SRAM)-based as well as comparator-based designs. Unfortunately, these SRAM-based and comparator-based designs exhibit a large footprint, which significantly increases the size of an integrated circuit (IC) incorporating these designs. Additionally, conventional implementation of neuromorphic neural hardware activation functions rely on a substantial number of active devices, which consume a significant amount of power in the digital domain. An ideal artificial neuron possessing bio-inspired behaviors as exemplified by the requisite leaky-integrate-fire and self-reset (LIFR) functionalities within a single device is still lacking. An embedded multi-time programmable (MTP) floating gate memory cell fabricated using a semiconductor-on-insulator (SOI) complementary metal oxide semiconductor (CMOS) process to enable neuromorphic neural hardware multiply-accumulate (MAC) functions is desired.

FIGS. 3A and 3B are diagrams illustrating a neuromorphic network 300 of synthetic neurons interconnected among synaptic devices to imitate the functions of the brain, according to various aspects of the present disclosure. As shown in FIG. 3A, the neuromorphic network 300 is configured as a fully connected (FC) neural network, including interconnected input neurons 320, hidden neurons 330, and output neurons 350. In this example, classification of an object 310 is performed, in which depth information for the object 310 is presented as spike delays 302, which are shown with associated noise 304 in response to light detection and ranging (LiDAR) fires 306, in response to the object 310, before a next fire 308 of the interconnected input neurons 320. In this example, a first to fire neuron 352 of the output neurons 350 classifies the object 310 as a pedestrian from a group of target objects 360.

FIG. 3B is a block diagram further illustrating one of the hidden neurons 330 shown in FIG. 3A, in accordance with various aspects of the present disclosure. As shown in FIG. 3B, the one of the hidden neurons 330 includes a leaky integrate-fire and reset (LIFR) portion 332 and a multiply-accumulate (MAC) portion 340. The LIFR portion 332 is further described in co-pending U.S. patent application Ser. No.______. In some aspects of the present disclosure, the MAC portion 340 is implemented using a semiconductor-on-insulator (SOI) complementary metal oxide semiconductor (CMOS) process for enabling neuromorphic neural hardware activation MAC functions.

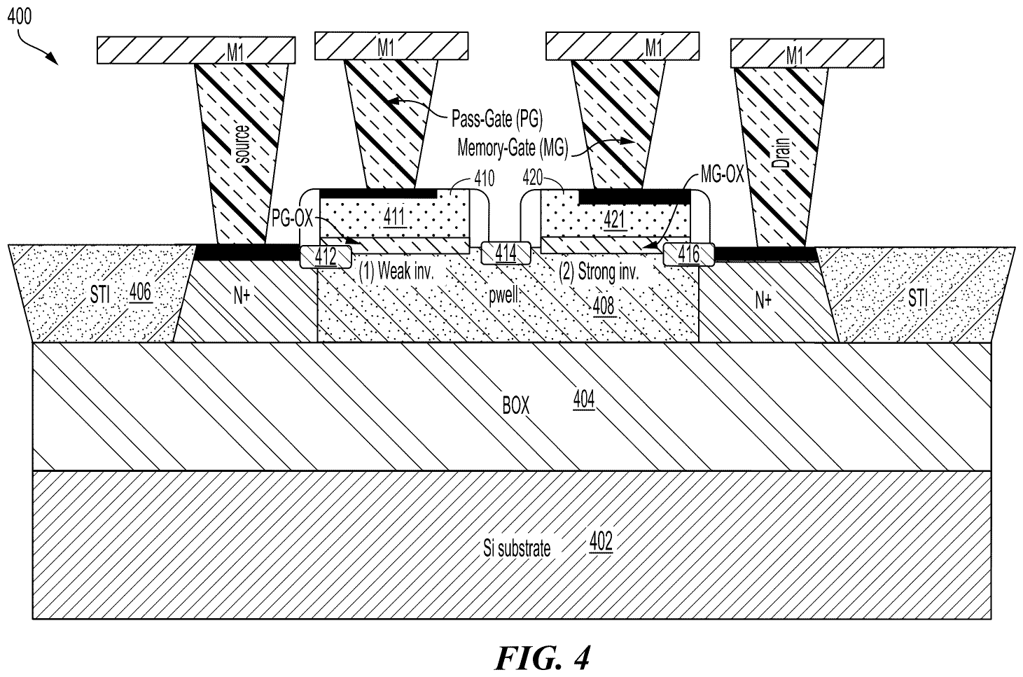

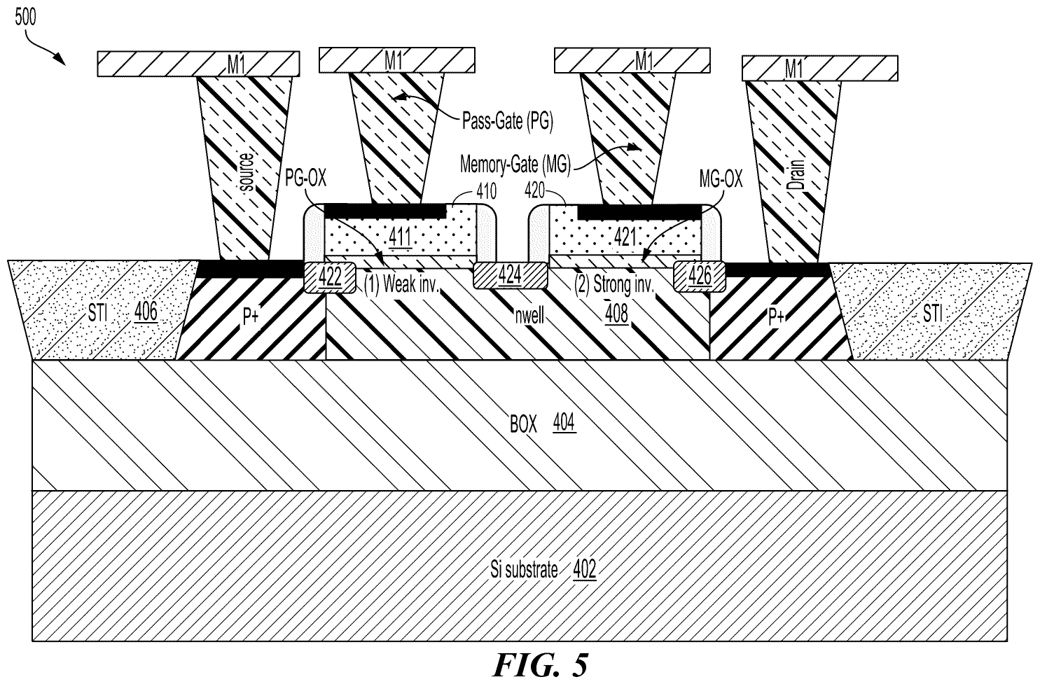

FIG. 4 illustrates a cross-sectional view of an embedded multi-time programmable (MTP) memory cell implementation of the multiply-accumulate (MAC) portion 340 of FIG. 3B, according to various aspects of the present disclosure. As shown in FIG. 4, an embedded MTP memory cell 400 is implemented using a semiconductor-on-insulator (SOI) complementary metal oxide semiconductor (CMOS) process to enable neuromorphic neural hardware MAC functions of the MAC portion 340 of FIG. 3B. In this configuration, the embedded MTP memory cell 400 includes a substrate 402 supporting a buried oxide (BOX) layer 404, which supports a shallow trench isolation layer 406 and an SOI layer 408. In this example, the SOI layer 408 includes N+ source and drain diffusion regions, having a P-type well (P-well) between the N+ diffusion regions.

According to various aspects of the present disclosure, the embedded MTP memory cell 400 is an SOI N-type field effect transistor (FET), having a planar multi-gate structure, including a pass-gate 410 and a memory-gate 420 on the SOI layer 408. The pass-gate 410 includes a polysilicon layer 411 between adjoining sidewalls, and the memory-gate 420 includes a polysilicon 421 layer between adjoining sidewalls. In this example, a pass-gate oxide (PG-OX) and a memory-gate oxide (MG-OX) are implemented as thick oxide devices. As described in further detail below, the term “pass-gate” refers to a storage control mechanism, and the term “memory-gate” refers to the storage area of programmed data. For example, activation of the pass-gate 410 controls storage of a programmed value in the memory-gate 420.

In various aspects of the present disclosure, a thickness of the MG-OX is increased to provide improved charge retention, and a thickness of the PG-OX is reduced to provide improved channel control. In this example, the increased thickness of the MG-OX is with respect to a thickness of the PG-OX and the decreased thickness of the PG-OX is relative to a native transistor gate oxide thickness. In this configuration, the increased thickness of the MG-OX results in a strong inversion (2), and the decreased thickness of the PG-OX results in a weak inversion (1).

Additionally, a pass-gate extension region 412, a combination extension region 414, and a memory-gate extension region 416 are also shown. In some implementations, diffusion values of the pass-gate extension region 412, the combination extension region 414, and the memory-gate extension region 416 are adjusted. For example, the diffusion values of the pass-gate extension region 412, the combination extension region 414, and the memory-gate extension region 416 can be adjusted to enhance a current passing property of the pass-gate 410 and/or a programming capability of the memory-gate 420.

As shown in FIG. 4, the embedded MTP memory cell 400 includes source/drain contacts to the N+ diffusion regions as well as gate contacts to the pass-gate 410 and the memory-gate 420 using, for example, a silicide layer. In this example, first back-end-of-line metal layers M1 are respectively coupled to the source/drain contacts as well as the gate contacts to the pass-gate 410 and the memory-gate 420. In operation, the embedded MTP memory cell 400 may be programmed as follows. First, the pass-gate 410 is turned “ON” (e.g., Vgs=1.5 V). Once the pass-gate 410 is turned “ON,” a program voltage (Vprog) is applied on the memory-gate 420 to pull electrons into the MG-OX. In this example, a threshold voltage (Vt) of the embedded MTP memory cell 400 is set based on a time for which the pass-gate 410 and/or the memory-gate 420 is high.

FIG. 5 illustrates a cross-sectional view of an embedded multi-time programmable (MTP) memory cell implementation of the multiply-accumulate (MAC) portion 340 of FIG. 3B, according to various aspects of the present disclosure. As shown in FIG. 5, an embedded MTP memory cell 500 is implemented using a semiconductor-on-insulator (SOI) complementary metal oxide semiconductor (CMOS) process to enable neuromorphic neural hardware MAC functions of the MAC portion 340 of FIG. 3B. This configuration of the embedded MTP memory cell 500 is like the configuration of the embedded MTP memory cell 400 of FIG. 4 and described using similar reference numbers. In this configuration, an SOI layer 408 of the embedded MTP memory cell 500 includes P+ source and drain diffusion regions, having an N-type well (N-well) between the P+ diffusion regions.

According to various aspects of the present disclosure, the embedded MTP memory cell 500 is an SOI P-type field effect transistor (FET), having a planar multi-gate structure, including a pass-gate 410 and a memory-gate 420 on the SOI layer 408. In this example the PG-OX and the MG-OX are similarly implemented as thick oxide devices, in which the increased thickness of the MG-OX results in a strong inversion 422, and the decreased thickness of the PG-OX results in a weak inversion (1). In operation, the embedded MTP memory cell 500 may be programmed as follows. First, the pass-gate 410 is turned “ON” (e.g., Vgs=1.5 V). Once the pass-gate 410 is turned “ON,” a program voltage (Vprog) is applied on the memory-gate 420 to pull electrons into the MG-OX. In this example, a threshold voltage (Vt) of the embedded MTP memory cell 500 is set based on a time for which the pass-gate 410 and/or the memory-gate 420 is high.

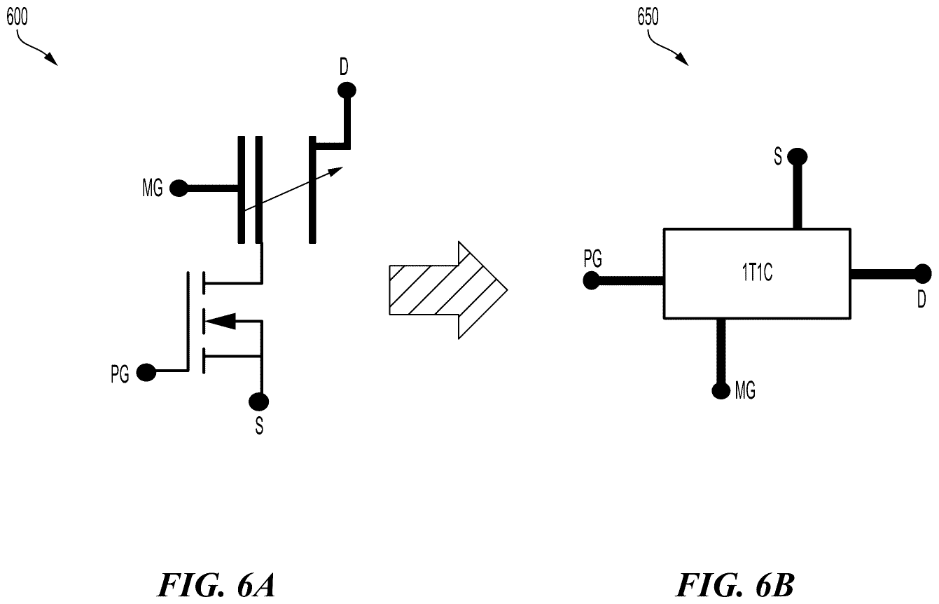

FIGS. 6A and 6B illustrate a circuit diagram and a corresponding block diagram of the embedded multi-time programmable (MTP) memory cell 500 of FIG. 5, according to various aspects of the present disclosure. FIG. 6A illustrates a circuit diagram 600 of the embedded MTP memory cell 500 of FIG. 5, in which an arrow represents the increased thickness of the MG-OX of the memory-gate 420 (MG). Additionally, a drain terminal (D) is coupled to the memory-gate 420 (MG) and a source terminal (S) is coupled to the pass-gate 410 (PG).

FIG. 6B illustrates a block diagram 650 of the embedded MTP memory cell 500 of FIG. 5, in which the MTP memory cell is shown as a four-terminal one-transistor, one capacitor (1T1C) device for enabling neuromorphic neural hardware activation multiply-accumulate (MAC) functions. In some implementations, the embedded MTP memory cell 500 is composed of a multi-gate N-type field effect transistor (FET). In other implementations, the embedded MTP memory cell 500 is composed of a multi-gate P-type field effect transistor (FET).

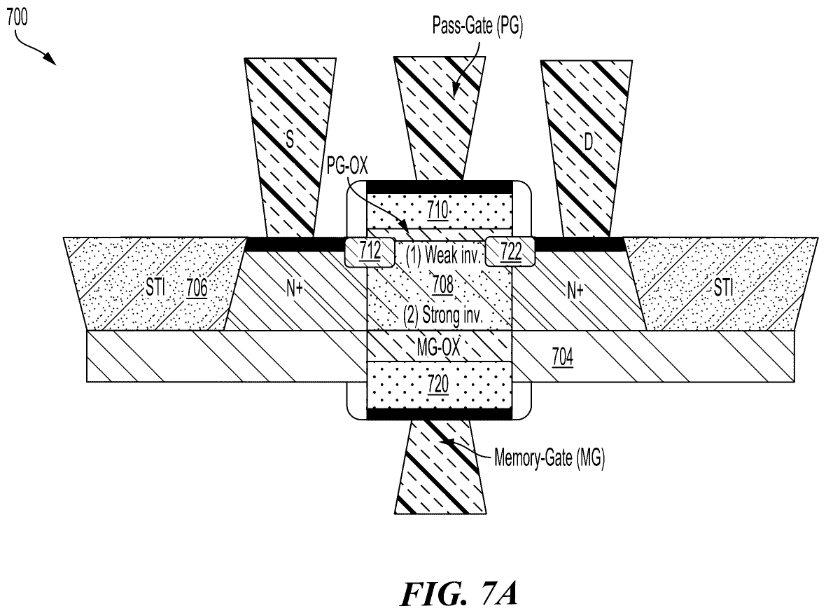

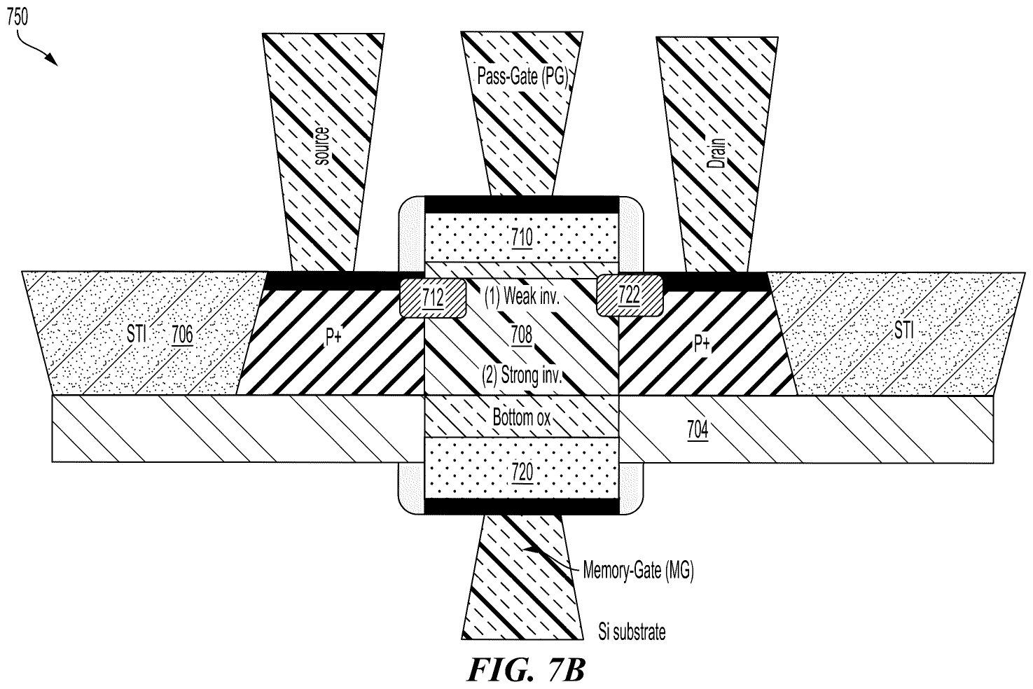

FIGS. 7A and 7B illustrate cross-sectional views of embedded multi-time programmable (MTP) memory cell implementations of the multiply-accumulate (MAC) portion 340 of FIG. 3B, according to various aspects of the present disclosure. FIG. 7A illustrates a configuration of an MTP memory cell 700 utilizing a three-dimensional (3D) stacked pass-gate and back-memory-gate structure floating gate device that is a variation of the semiconductor-on-insulator (SOI) N-type field effect transistor (FET) configuration of the embedded MTP memory cell 400 of FIG. 4. In this example, a BOX layer 704 supports a shallow trench isolation (STI) layer 706 and an SOI layer 708. In this configuration, the SOI layer 708 of the MTP memory cell 700 includes N+ source and drain diffusion regions, having a P-type well (P-well) between the N+ diffusion regions.

According to various aspects of the present disclosure, the MTP memory cell 700 is an SOI N-type FET, having a 3D stacked multi-gate structure, including a pass-gate 710 and a memory-gate 720 on a backside of the SOI layer 708 and distal (e.g., opposite) from the pass-gate 710. In this example, the pass-gate 710 includes a first pass-gate extension region 712 and a second pass-gate extension region 722. For example, the diffusion values of the first pass-gate extension region 712, the second pass-gate extension region 772 can be adjusted to enhance a current passing property of the pass-gate 710 and/or a programming capability of the memory-gate 720. The pass-gate 710 and the memory-gate 720 include a polysilicon layer between adjoining sidewalls. In this example, a pass-gate oxide (PG-OX) and a memory-gate oxide (MG-OX) are implemented as thick oxide devices. In various aspects of the present disclosure, a thickness of the MG-OX is increased to provide improved charge retention and a thickness of the PG-OX is reduced to provide improved channel control.

In various aspects of the present disclosure, a thickness (e.g., 5 nanometers to 10 nanometers) of the MG-OX is increased to provide improved charge retention, and a thickness (e.g., 2 nanometers to 5 nanometers) of the PG-OX is reduced to provide improved channel control. In this example, the increased thickness of the MG-OX is with respect to a thickness of the PG-OX and the decreased thickness of the PG-OX is relative to a native transistor gate oxide thickness. For example, In this configuration, the increased thickness of the MG-OX results in a strong inversion (2), and the decreased thickness of the PG-OX results in a weak inversion (1).

As shown in FIG. 7A, the MTP memory cell 700 includes source/drain contacts to the N+ diffusion regions as well as gate contacts to the pass-gate 710 and the memory-gate 720 using, for example, a silicide layer. In operation, the MTP memory cell 700 is programmed to pull electrons into the MG-OX for storing charge. In various aspects of the present disclosure, the MTP memory cell 700 is formed using a process, in which the memory-gate 720 is secured to the SOI layer 708 once the process completes.

For example, the process (e.g., a layer transfer process) is performed to prepare the backside of the MG-OX to allow for formation of the memory-gate 720. This process may include formation of a backside memory-gate via, followed by a backside silicon/semiconductor removal. Next, a cavity etch is performed to reduce the BOX thickness to the specified MG-OX thickness. This is followed by deposition of the gate material (e.g., a polysilicon layer or metal layer) and then forming the contact. This entire process is possible by placing the main wafer on a temporary carrier wafer and then flipping the wafer to perform the backside processing.

FIG. 7B illustrates a cross-sectional view of an MTP memory cell 750 implementation of the MAC portion 340 of FIG. 3B, according to various aspects of the present disclosure. This configuration of the MTP memory cell 750 is like the configuration of the MTP memory cell 700 of FIG. 7A and described using similar reference numbers. In this configuration, the SOI layer 708 of the MTP memory cell 750 includes P+ source and drain diffusion regions, having an N-type well (N-well) between the P+ diffusion regions.

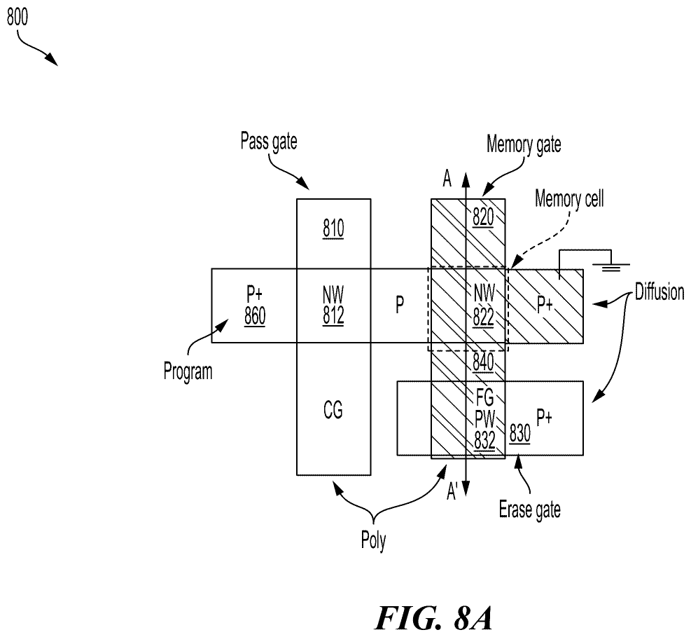

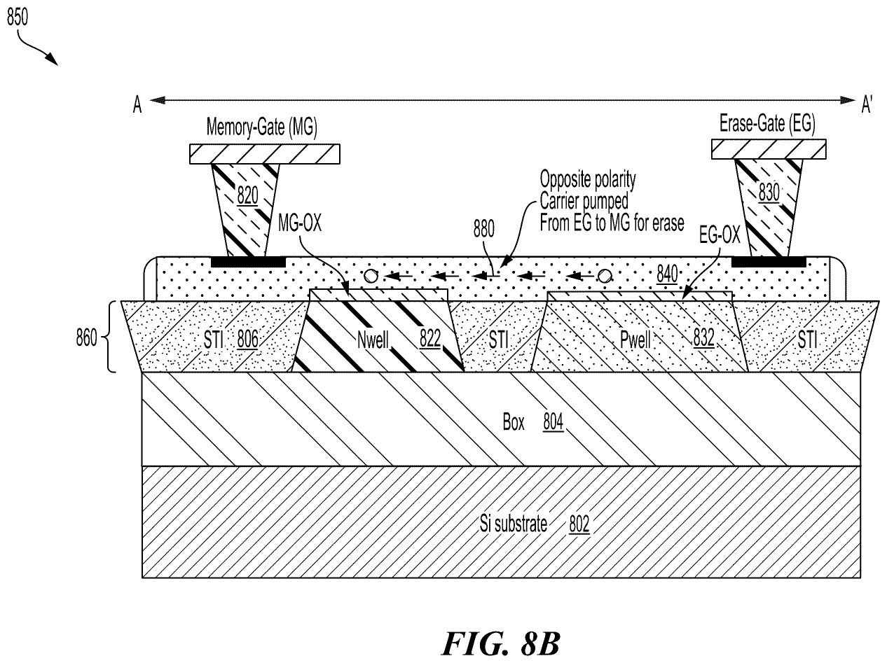

FIGS. 8A and 8B illustrate layout and cross-sectional views of embedded multi-time programmable (MTP) memory cell implementations of the multiply-accumulate (MAC) portion 340 of FIG. 3B, according to various aspects of the present disclosure.

FIG. 8A illustrates a configuration of an MTP memory cell 800 utilizing an erase gate design, according to various aspects of the present disclosure. In this configuration of the MTP memory cell 800, a pass-gate 810 is configured as a control gate and a memory-gate 820 is configured as a floating gate that is a variation of the semiconductor-on-insulator (SOI) N-type field effect transistor (FET) configuration of the embedded MTP memory cell 400 of FIG. 4. As shown in FIG. 8A, the MTP memory cell 800 includes an erase-gate 830 that is configured as a floating gate and coupled to a P-well region 832 of the memory-gate 820, including a polysilicon layer 840. Additionally, an SOI layer 860 is coupled to an N-type well (N-well) region 812 of the pass-gate 810 and an N-well region 822 of the memory-gate 820. A cross-sectional view of the MTP memory cell 800 along the cutline AA′ is shown in FIG. 8B.

FIG. 8B illustrates a cross-sectional view 850 of the MTP memory cell 800 of FIG. 8A along the cutline AA′, according to various aspects of the present disclosure. In this configuration, the MTP memory cell 800 includes a substrate 802 supporting a buried oxide (BOX) layer 804, which supports a shallow trench isolation (STI) layer 806 and an SOI layer 860. In this example, the SOI layer 860 includes the N-well region 822 and the P-well region 832, separated by a portion of the STI layer 806. In this example, a memory-gate oxide (MG-OX) is provided on the N-well region 822, and an erase gate oxide (EG-OX) is provided on the P-well region 832. As noted above, the MG-OX is implemented as a thick (e.g., 3 nm-7 nm) oxide device; however, the EG-OX may be implemented using a thin (e.g., 1 nm-3 nm) oxide (e.g., if not leaky) to increase a coupling capacitance for performing an erase operation.

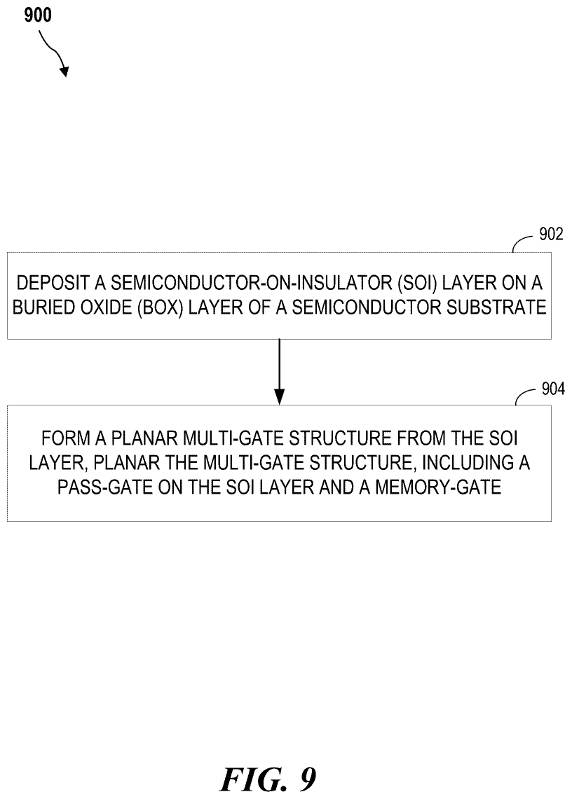

In various aspects of the present disclosure, a polysilicon layer 840 is on the SOI layer 860, including the STI layer 806 as well as the MG-OX and the EG-OX. In this configuration, an erase operation provided by the erase-gate 830 pumps an opposite polarity carrier 880 from the erase-gate 830 to the memory-gate 820 to clear the contents of the memory-gate 820. Operation of the erase-gate 830 is improved by utilizing an increased capacitance for strong coupling with the SOI layer 860 (e.g., main island). As described, the main island may refer to the region of the SOI layer 860 from where the opposite polarity carriers are pushed into the memory-gate 820. For an N-type memory gate (e.g., N-well region 822) holes are push and for a P-type memory gate (e.g., P-well region 832) electrons are push. In operation, the increased coupling capacitance is achieved by utilizing a thin oxide to implement the EG-OX, provided the erase-gate 830 is not leaky. Additionally, the SOI layer 860 supports stacking of the memory-gate 820 and the erase-gate 830 with an increased proximity (e.g., 30 nm to 100 nm), which helps reduce issues associated with latch-up. An embedded MTP memory cell formation process is illustrated, for example, in FIG. 9.

FIG. 9 is a flow diagram illustrating a process 900 for formation of a multi-time programmable (MTP) memory cell, according to aspects of the present disclosure. The process 900 begins at block 902, in which a semiconductor-on-insulator (SOI) layer is deposited on a buried oxide (BOX) layer of a semiconductor substrate. For example, as shown in FIG. 4, the embedded MTP memory cell 400 includes a substrate 402 supporting a buried oxide (BOX) layer 404, which supports a shallow trench isolation layer 406 and an SOI layer 408. In this example, the SOI layer 408 includes N+ source and drain diffusion regions, having a P-type well (P-well) between the N+ diffusion regions.

At block 904, a planar multi-gate structure is formed from the SOI layer. The planar the multi-gate structure includes a pass-gate on the SOI layer and a memory-gate. For example, as shown in FIG. 4, the embedded MTP memory cell 400 is an SOI N-type field effect transistor (FET), having a planar multi-gate structure, including a pass-gate 410 and a memory-gate 420 on the SOI layer 408. The pass-gate 410 includes a polysilicon layer 411 between adjoining sidewalls, and the memory-gate 420 includes a polysilicon 421 layer between adjoining sidewalls. In this example, a pass-gate oxide (PG-OX) and a memory-gate oxide (MG-OX) are implemented as thick oxide devices.

In some aspects, the process 900 may be performed by the SoC 100 (FIG. 1). That is, each of the elements of the process 900 may, for example, but without limitation, be performed by the SoC 100 or one or more processors (e.g., CPU 102 and/or NPU 130) and/or other components included therein.

Implementation examples are described in the following numbered clauses:
1. A multi-time programable (MTP) memory cell, comprising:
   a buried oxide (BOX) layer;
   a semiconductor-on-insulator (SOI) layer on the BOX layer; and
   a planar multi-gate structure, comprising:
      a pass-gate on the SOI layer, and
      a memory-gate.
2. The MTP memory cell of clause 1, in which the memory-gate is on the BOX layer, distal from the pass-gate.
3. The MTP memory cell of any of clauses 1 or 2, in which the pass-gate has a first gate oxide thickness, and the memory-gate has a second gate oxide thickness greater than the first gate oxide thickness.
4. The MTP memory cell of any of clauses 1-3, further comprising an erase-gate on a polysilicon layer of the memory-gate.
5. The MTP memory cell of clause 4, in which the erase-gate has a first gate oxide thickness, and the memory-gate has a second gate oxide thickness greater than the first gate oxide thickness.
6. The MTP memory cell of clause 4, in which the erase-gate is proximate a P-type well (P-well) region of the SOI layer.
7. The MTP memory cell of clause 4, in which the erase-gate comprises a floating gate and the pass-gate comprises a control gate.
8. The MTP memory cell of any of clauses 1-7, in which the MTP memory cell comprises a multi-gate N-type field effect transistor (FET).
9. The MTP memory cell of any of clauses 1-7, in which the MTP memory cell comprises a multi-gate P-type field effect transistor (FET).
10. The MTP memory cell of any of clauses 1-9, in which the MTP memory cell is integrated into a neuromorphic computing (NC) hardware activation (NCHWA) of a neural processing unit (NPU).
11. A processor-implemented method for formation of a multi-time programmable (MTP) memory cell, the method comprising:
   depositing a semiconductor-on-insulator (SOI) layer on a buried oxide (BOX) layer of a semiconductor substrate; and
   forming a planar multi-gate structure from the SOI layer, planar the multi-gate structure comprising:
      a pass-gate on the SOI layer, and
      a memory-gate.
12. The method of clause 11, in which the memory-gate is on the BOX layer, distal from the pass-gate.
13. The method of any of clauses 11 or 12, in which the pass-gate has a first gate oxide thickness, and the memory-gate has a second gate oxide thickness greater than the first gate oxide thickness.
14. The method of any of clauses 11-13, further comprising an erase-gate on a polysilicon layer of the memory-gate.
15. The method of clause 14, in which the erase-gate has a first gate oxide thickness, and the memory-gate has a second gate oxide thickness greater than the first gate oxide thickness.
16. The method of clause 14, in which the erase-gate is proximate a P-type well (P-well) region of the SOI layer.
17. The method of clause 14, in which the erase-gate comprises a floating gate and the pass-gate comprises a control gate.
18. The method of any of clauses 11-17, in which the MTP memory cell comprises a multi-gate N-type field effect transistor (FET).
19. The method of any of clauses 11-17, in which the MTP memory cell comprises a multi-gate P-type field effect transistor (FET).
20. The method of any of clauses 11-19, in which the MTP memory cell is integrated into a neuromorphic computing (NC) hardware activation (NCHWA) of a neural processing unit (NPU).

The various operations of methods described above may be performed by any suitable means capable of performing the corresponding functions. The means may include various hardware and/or software component(s) and/or module(s), including, but not limited to, a circuit, an application specific integrated circuit (ASIC), or processor. Where there are operations illustrated in the figures, those operations may have corresponding counterpart means-plus-function components with similar numbering.

As used, the term “determining” encompasses a wide variety of actions. For example, “determining” may include calculating, computing, processing, deriving, investigating, looking up (e.g., looking up in a table, a database, or another data structure), ascertaining and the like. Additionally, “determining” may include receiving (e.g., receiving information), accessing (e.g., accessing data in a memory) and the like. Furthermore, “determining” may include resolving, selecting, choosing, establishing, and the like.

As used, a phrase referring to “at least one of” a list of items refers to any combination of those items, including single members. As an example, “at least one of: a, b, or c” is intended to cover: a, b, c, a-b, a-c, b-c, and a-b-c.

The various illustrative logical blocks, modules and circuits described in connection with the present disclosure may be implemented or performed with a general purpose processor, a digital signal processor (DSP), an application specific integrated circuit (ASIC), a field programmable gate array signal (FPGA) or other programmable logic device (PLD), discrete gate or transistor logic, discrete hardware components or any combination thereof designed to perform the functions described. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in any form of storage medium that is known in the art. Some examples of storage media that may be used include random-access memory (RAM), read-only memory (ROM), flash memory, erasable programmable read-only memory (EPROM), electrically erasable programmable read-only memory (EEPROM), registers, a hard disk, a removable disk, a CD-ROM, and so forth. A software module may comprise a single instruction, or many instructions, and may be distributed over several different code segments, among different programs, and across multiple storage media. A storage medium may be coupled to a processor such that the processor can read information from, and write information to, the storage medium. In the alternative, the storage medium may be integral to the processor.

The methods disclosed, include one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a device. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement signal processing functions. For certain aspects, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processor may be responsible for managing the bus and general processing, including the execution of software stored on the machine-readable media. The processor may be implemented with one or more general purpose and/or special-purpose processors. Examples include microprocessors, microcontrollers, DSP processors, and other circuitry that can execute software. Software shall be construed broadly to mean instructions, data, or any combination thereof, whether referred to as software, firmware, middleware, microcode, hardware description language, or otherwise. Machine-readable media may include, by way of example, random-access memory (RAM), flash memory, read-only memory (ROM), programmable read-only memory (PROM), erasable programmable read-only memory (EPROM), electrically erasable programmable read-only memory (EEPROM), registers, magnetic disks, optical disks, hard drives, or any other suitable storage medium, or any combination thereof. The machine-readable media may be embodied in a computer-program product. The computer-program product may comprise packaging materials.

In a hardware implementation, the machine-readable media may be part of the processing system separate from the processor. However, as those skilled in the art will readily appreciate, the machine-readable media, or any portion thereof, may be external to the processing system. By way of example, the machine-readable media may include a transmission line, a carrier wave modulated by data, and/or a computer product separate from the device, all which may be accessed by the processor through the bus interface. Alternatively, or in addition, the machine-readable media, or any portion thereof, may be integrated into the processor, such with cache and/or general register files. Although the various components discussed may be described as having a specific location, such as a local component, they may also be configured in several ways, such as certain components being configured as part of a distributed computing system.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may comprise one or more neuromorphic processors for implementing the neuron models and models of neural systems described. As another alternative, the processing system may be implemented with an application specific integrated circuit (ASIC) with the processor, the bus interface, the user interface, supporting circuitry, and at least a portion of the machine-readable media integrated into a single chip, or with one or more field programmable gate arrays (FPGAs), programmable logic devices (PLDs), controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the application and the overall design constraints imposed on the overall system.

The machine-readable media may comprise several software modules. The software modules include instructions that, when executed by the processor, cause the processing system to perform various functions. The software modules may include a transmission module and a receiving module. Each software module may reside in a single storage device or be distributed across multiple storage devices. By way of example, a software module may be loaded into RAM from a hard drive when a triggering event occurs. During execution of the software module, the processor may load some of the instructions into cache to increase access speed. One or more cache lines may then be loaded into a general register file for execution by the processor. When referring to the functionality of a software module below, it will be understood that such functionality is implemented by the processor when executing instructions from that software module. Furthermore, it should be appreciated that aspects of the present disclosure result in improvements to the functioning of the processor, computer, machine, or other system implementing such aspects.

If implemented in software, the functions may be stored or transmitted over as one or more instructions or code on a computer-readable medium. Computer-readable media include both computer storage media and communication media including any medium that facilitates transfer of a computer program from one place to another. A storage medium may be any available medium that can be accessed by a computer. By way of example, and not limitation, such computer-readable media can comprise RAM, ROM, EEPROM, CD-ROM or other optical disk storage, magnetic disk storage, or other magnetic storage devices, or any other medium that can be used to carry or store desired program code in the form of instructions or data structures and that can be accessed by a computer. Additionally, any connection is properly termed a computer-readable medium. For example, if the software is transmitted from a website, server, or other remote source using a coaxial cable, fiber optic cable, twisted pair, digital subscriber line (DSL), or wireless technologies such as infrared (IR), radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk, and Blu-ray® disc, where disks usually reproduce data magnetically, while discs reproduce data optically with lasers. Thus, in some aspects, computer-readable media may comprise non-transitory computer-readable media (e.g., tangible media). In addition, for other aspects computer-readable media may comprise transitory computer-readable media (e.g., a signal). Combinations of the above should also be included within the scope of computer-readable media.

Thus, certain aspects may comprise a computer program product for performing the operations presented. For example, such a computer program product may comprise a computer-readable medium having instructions stored (and/or encoded) thereon, the instructions being executable by one or more processors to perform the operations described herein. For certain aspects, the computer program product may include packaging material.

Further, it should be appreciated that modules and/or other appropriate means for performing the methods and techniques described herein, may be downloaded and/or otherwise obtained by a user terminal and/or base station as applicable. For example, such a device can be coupled to a server to facilitate the transfer of means for performing the methods described herein. Alternatively, various methods described herein, may be provided via storage means (e.g., RAM, ROM, a physical storage medium such as a compact disc (CD) or floppy disk, etc.), such that a user terminal and/or base station can obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. A multi-time programable (MTP) memory cell, comprising:
a buried oxide (BOX) layer;
a semiconductor-on-insulator (SOI) layer on the BOX layer; and
a planar multi-gate structure, comprising:
a pass-gate on the SOI layer, and
a memory-gate.

2. The MTP memory cell of claim 1, in which the memory-gate is on the BOX layer, distal from the pass-gate.

3. The MTP memory cell of claim 1, in which the pass-gate has a first gate oxide thickness, and the memory-gate has a second gate oxide thickness greater than the first gate oxide thickness.

4. The MTP memory cell of claim 1, further comprising an erase-gate on a polysilicon layer of the memory-gate.

5. The MTP memory cell of claim 4, in which the erase-gate has a first gate oxide thickness, and the memory-gate has a second gate oxide thickness greater than the first gate oxide thickness.

6. The MTP memory cell of claim 4, in which the erase-gate is proximate a P-type well (P-well) region of the SOI layer.

7. The MTP memory cell of claim 4, in which the erase-gate comprises a floating gate and the pass-gate comprises a control gate.

8. The MTP memory cell of claim 1, in which the MTP memory cell comprises a multi-gate N-type field effect transistor (FET).

9. The MTP memory cell of claim 1, in which the MTP memory cell comprises a multi-gate P-type field effect transistor (FET).

10. The MTP memory cell of claim 1, in which the MTP memory cell is integrated into a neuromorphic computing (NC) hardware activation (NCHWA) of a neural processing unit (NPU).

11. A processor-implemented method for formation of a multi-time programmable (MTP) memory cell, the method comprising:
depositing a semiconductor-on-insulator (SOI) layer on a buried oxide (BOX) layer of a semiconductor substrate; and
forming a planar multi-gate structure from the SOI layer, planar the multi-gate structure comprising:
a pass-gate on the SOI layer, and
a memory-gate.

12. The method of claim 11, in which the memory-gate is on the BOX layer, distal from the pass-gate.

13. The method of claim 11, in which the pass-gate has a first gate oxide thickness, and the memory-gate has a second gate oxide thickness greater than the first gate oxide thickness.

14. The method of claim 11, further comprising an erase-gate on a polysilicon layer of the memory-gate.

15. The method of claim 14, in which the erase-gate has a first gate oxide thickness, and the memory-gate has a second gate oxide thickness greater than the first gate oxide thickness.

16. The method of claim 14, in which the erase-gate is proximate a P-type well (P-well) region of the SOI layer.

17. The method of claim 14, in which the erase-gate comprises a floating gate and the pass-gate comprises a control gate.

18. The method of claim 11, in which the MTP memory cell comprises a multi-gate N-type field effect transistor (FET).

19. The method of claim 11, in which the MTP memory cell comprises a multi-gate P-type field effect transistor (FET).

20. The method of claim 11, in which the MTP memory cell is integrated into a neuromorphic computing (NC) hardware activation (NCHWA) of a neural processing unit (NPU).
